(19) United States
(12) Patent Application Publication
(10) Pub. No.: US 2016/0301359 A1
(43) Pub. Date: Oct. 13, 2016

(54) PHOTOVOLTAIC STRUCTURE

(71) Applicant: COMMISSARIAT A L'ENERGIE ATOMIQUE ET AUX ENERGIES ALTERNATIVES, Paris (FR)

(72) Inventors: Eric Gerritsen, Bernin (FR); Christophe Mangeant, Yenne (FR)

(73) Assignee: COMMISSARIAT A L'ENERGIE ATOMIQUE ET AUX ENERGIES ALTERNATIVES, Paris (FR)

(21) Appl. No.: 15/100,739

(22) PCT Filed: Dec. 17, 2014
(86) PCT No.: PCT/EP2014/078298

§ 371 Date: Jun. 1, 2016

(30) Foreign Application Priority Data
Dec. 18, 2013 (FR) 1362894

(51) Int. Cl. H02S 40/22; H02S 20/30; H02S 40/36; H01L 31/068

(52) U.S. Cl. CPC H02S 40/22; H01L 31/0684; H02S 20/30; H02S 40/36

(57) ABSTRACT

The invention relates to a photovoltaic structure comprising a first wall and a second wall defining an inner space therebetween, the first wall being at least partially transparent to solar radiation, the second wall comprising an inner surface that is at least partially reflective with respect to solar radiation across from the inner surface of the first wall, the first wall being part of a closed enclosure and the second wall being arranged inside said enclosure, and photovoltaic modules each comprising a plurality of bifacial photovoltaic cells, arranged on the outer surface of the first wall, such that when the structure is exposed to solar radiation, a first portion of the incident radiation is transmitted to the outer surface of said bifacial photo voltaic cells, and a second portion of said incident radiation is transmitted through a portion of the first wall and reflects at least partially on the inner surface of the second wall, said reflected portion being transmitted through the first wall to the inner surface of the bifacial photovoltaic cells.

### FIELD OF THE INVENTION

The present invention concerns a photovoltaic structure comprising a first wall and a second wall defining an inner space therebetween, a plurality of photovoltaic modules being arranged on the first wall.

### BACKGROUND OF THE INVENTION

The aeronautical sector has taken advantage of the increasing lightness of materials, which has made it possible to manufacture photovoltaic modules for designing flying objects (for example lenticular airships) equipped with such modules to provide an electrical power supply for said object.

The flying object thus comprises a carrier structure comprising two walls defining a closed space therebetween, the closed space containing a light gas, a convex upper wall (upper surface) intended to be exposed to solar radiation and a lower wall with an opposite curvature to that of the upper wall (lower surface).

Photovoltaic modules are arranged on the upper wall by means of a hook system which allows them to be dismounted.

Owing to the materials used, these photovoltaic modules are very light: they are typically composed of a stack of a composite material backing, an encapsulant, photovoltaic cells, an encapsulant, and a protective front face.

Given the rotational symmetry of the object, the photovoltaic modules are distributed in different angular sectors, the modules of one and the same sector being linked in series and each sector being linked to a current converter which is itself linked to electrical batteries forming the energy source of the flying object.

However, the performance of this device in terms of energy production is penalized by variations in lighting (for example, the partial or total darkening of one or more sectors, by a cloud, or else non-uniform lighting of the different sectors depending on the orientation of the object with respect to the sun).

This problem is moreover not specific to flying objects but can also apply, for example, to objects floating in the sea or the ocean and carrying photovoltaic modules, or else to light structures (inflatable or dismountable marquees) intended for events (sporting or other types).

### BRIEF DESCRIPTION OF THE INVENTION

An aim of the invention is therefore to design a photovoltaic structure comprising a plurality of photovoltaic modules and having improved performance in terms of energy production, this being the case in spite of non-uniform lighting conditions of the different modules.

In accordance with the invention, a photovoltaic structure is proposed comprising a first wall and a second wall defining an inner space therebetween,

the first wall being at least partly transparent to solar radiation and comprising an outer face intended to be exposed to solar radiation and an inner face,

the second wall comprising an inner face facing the inner face of the first wall, said inner face of the second wall being at least partly reflective with regard to solar radiation, the first wall forming a part of a closed envelope and the second wall being arranged inside said envelope,

a plurality of photovoltaic modules each comprising a plurality of bifacial solar cells, said modules being arranged on the outer face of the first wall, each bifacial cell comprising an outer face intended to be exposed to incident solar radiation and an inner face facing the outer face of the first wall,

so that when the structure is exposed to solar radiation, a first portion of the incident radiation is transmitted toward the outer face of said bifacial photovoltaic cells, a second portion of said incident radiation is transmitted through a part of the first wall and at least partly reflects off the inner face of the second wall, said reflected portion being transmitted through the first wall toward the inner face of the bifacial photovoltaic cells.

The term “bifacial” is understood to mean a photovoltaic cell wherein each of the main faces is photoactive. Such cells can be obtained by metallizing the back face of a conventional cell only locally, for example in the form of a grid or any other shape. For the implementation of the invention, one may consider a bifacial cell in which at least 50% of the surface of each face is adapted to transmit an incident radiation. The bifacial cells currently available commercially have a performance ratio of the output obtained by the back face and the output obtained by the front face between 85 and 95%.

The term “at least partly transparent” is understood to mean that the first wall allows the transmission of at least a part of the intensity of the solar radiation. Typically, between 40% and 90% of the intensity of the solar radiation passes through the first wall.

The term “arranged inside the envelope” is understood to mean that the second wall is distinct from the walls of the envelope.

Advantageously, the envelope is gas—and liquid—tight.

Advantageously, the photovoltaic modules are arranged in a non-contiguous way on the first wall, a portion of the incident radiation being transmitted through a part of the first wall located between two non-contiguous photovoltaic modules.

According to an embodiment, the second wall is planar.

According to an embodiment, the second wall has a curvature adjusted as a function of the curvature of the first wall and of the distribution of the photovoltaic modules on the first wall to optimize the reflection of the incident radiation transmitted through a region of the first wall toward the inner face of the cells of said modules located in the opposite region of said first wall.

According to a particular embodiment, the structure comprises a device for actuating the second wall, adapted to adjust the curvature of said second wall as a function of the position of the structure with respect to the sun.

Advantageously, the structure has at least one plane or one axis of symmetry.

According to an embodiment, the first wall has a convex shape having a rotational symmetry and the photovoltaic modules are distributed over said first wall in a plurality of angular sectors, the photovoltaic modules of one and the same angular sector being linked in series.

A summit portion of the first wall can be without photovoltaic modules.

Particularly advantageously, all the photovoltaic modules arranged on the first wall are identical.

Preferably, the photovoltaic modules are arranged reversibly on the first wall.

The material of the first wall can comprise a glass fiber fabric; the second wall can be made of polyethylene terephthalate (PET) metallized on its inner face.

Another subject of the invention concerns a lenticular airship comprising a photovoltaic structure as described above, the envelope of said structure being filled with a carrier gas.

Another subject of the invention concerns a dome, particularly intended to float on the surface of a sea or an ocean, comprising a photovoltaic structure as described above.

### BRIEF DESCRIPTION OF THE DRAWINGS

Other features and advantages of the invention will become apparent from the following detailed description, with reference to the appended drawings wherein:

FIG. 1 is a section view of a photovoltaic structure in accordance with an embodiment of the invention,

FIG. 2 is a section view of the structure in FIG. 1 at the level of a photovoltaic module,

FIG. 3 is a perspective view of a photovoltaic structure according to a form of execution of the invention,

FIG. 4 is a perspective view of a means for fastening a module to the wall of the photovoltaic structure,

FIGS. 5A to 5C illustrate the distribution of the irradiance of the solar radiation over the surface of the first wall of the structure at three times (8:30 a.m., 2:00 p.m., 5:00 p.m.) in a day,

FIG. 6 is a section view of a photovoltaic structure according to another embodiment of the invention,

FIG. 7 is a section view of another photovoltaic structure,

FIG. 8 is a schematic diagram of a photovoltaic structure according to another embodiment of the invention.

### DETAILED DESCRIPTION OF EMBODIMENTS OF THE INVENTION

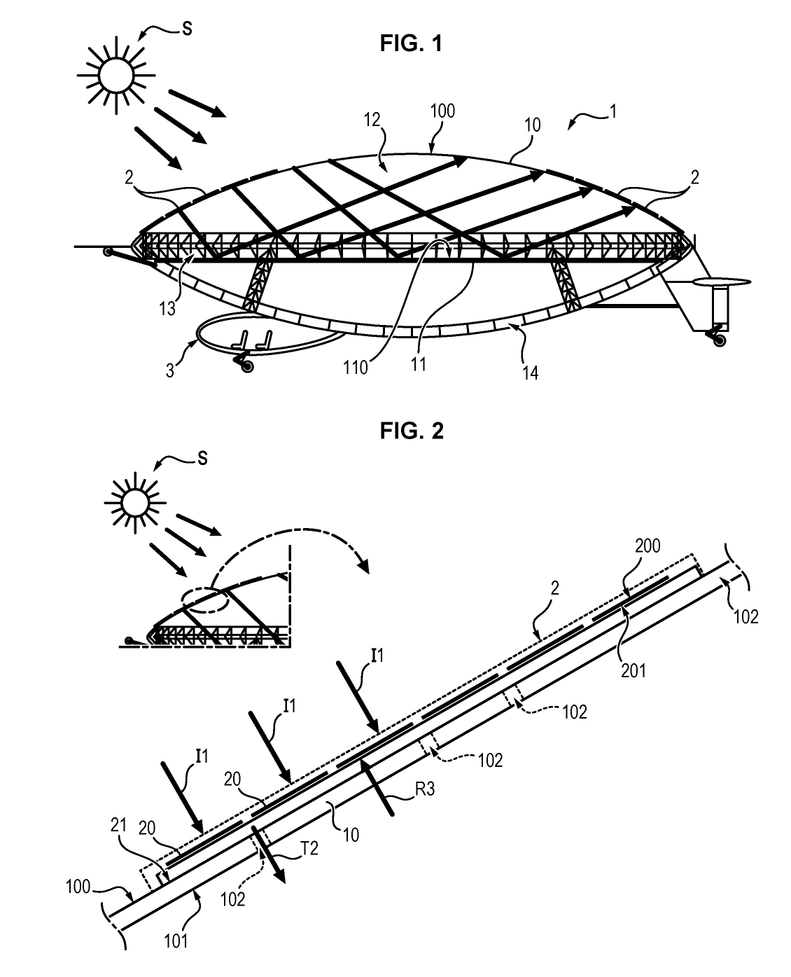

FIG. 1 is a section view of an embodiment wherein the photovoltaic structure is an airship.

Such a flying object has advantageous applications in observation missions, cartographic operations, or in the carriage of loads to areas that are difficult to access, for example in cities or mountains.

The invention is however not limited to this type of structure but can have other applications, particularly a dome, for example intended to float on the surface of a sea or an ocean, or else a marquee or a tent.

In general, the photovoltaic structure comprises two walls defining an inner space therebetween: a first wall at least partly transparent to solar radiation and comprising an outer face intended to be exposed to the solar radiation, and a second wall comprising an inner face facing the inner face of the first wall, said inner face of the second wall being at least partly reflective with regard to solar radiation.

Photovoltaic modules each comprising a plurality of bifacial photovoltaic cells are arranged on the outer face of the first wall.

When the structure is exposed to solar radiation the incident radiation is, in one part, directly transmitted to the bifacial cells through the outer face of said cells, which is exposed to said radiation, and in another part, transmitted through the first wall, especially by the possible intervals between the module as well as by the intervals between the photovoltaic cells, and enters the inner space.

This transmitted radiation is reflected by the reflective face of the second wall and transmitted to the bifacial cells through their inner face facing the first wall.

In FIG. 1, the structure 1 comprises a first wall 10 which, in this particular embodiment, forms the upper surface of the airship, and a second wall 14 which forms the lower surface. A cockpit 3 is arranged under the lower surface.

The two walls 10, 14 are held together by a rigid frame 13 and thus form a closed and watertight envelope delimiting an inner space 12 containing a carrier gas consisting of a light compressed gas to maintain the curvature of the two walls required for the lift of the structure.

The first wall 10 is made of a material that is light and at least partly transparent to solar radiation.

There are various materials suitable for this use: these particularly include polyurethanes, polyethylene terephthalate (PET), in particular marketed under the brand name Mylar™, as well as technical weaves marketed under the brand name Rivertex™,

The wall 10 comprises an outer face 100 intended to be exposed to solar radiation, and an inner face 101 which is directed toward the inner space 12.

The thickness of the wall 10 is typically between 0.2 and 1 mm.

Advantageously, the wall 14 is made of the same material as the wall 10.

Inside the envelope formed by the walls 10, 14 a wall 11 is arranged having an at least partly reflective inner face 110 located facing the inner face 101 of the wall 10.

The wall 11 is advantageously held up by the frame 13.

The wall 11 can be formed by a cloth, the inner face 110 of which is coated with a reflective coating.

According to an advantageous embodiment, the wall 11 can be formed by a backing metallized on its face 110. For example the wall 11 can be made of transparent polymer such as PET, PMMA or PC, covered with a reflective layer. The reflective layer is advantageously a metallic layer, for example aluminum or silver.

On its face 100 which is intended to be exposed to solar radiation, the wall 10 is partly coated with photovoltaic modules 2.

These photovoltaic modules are generally not contiguous.

In particular, there is an interval between two contiguous photovoltaic modules, this interval being specifically due to the fact that the modules 2 are generally rectangular whereas, in this embodiment, the wall 10 has a rotational shape.

Another reason for the existence of an interval between the modules is that the number of modules is limited by the mass of the photovoltaic structure, which generally does not allow for the placing of modules over the whole surface of the wall forming the upper surface.

Moreover, the apex of the structure is generally not equipped with photovoltaic modules. Indeed, when the modules are connected in series over an angular sector of the wall forming the upper surface, the power produced by said sector is limited by the photovoltaic module subject to the weakest lighting. Thus, placing photovoltaic modules all the way up to the apex of the upper surface is generally avoided to avoid a lighting defect in this region penalizing the whole sector.

In structure 1, a considerable part 102 of the surface of the wall 10 is therefore not masked by the photovoltaic modules and allows the incident radiation to pass through said wall.

This significant part of the radiation transmitted into the inner space 12 is at least partly recovered by means of the reflective face 110 of the wall 11, and directed toward the bifacial cells and in particular toward the back faces of the bifacial cells.

Regarding this, the fact that the partly reflective wall is arranged in the envelope and does not form part of this envelope (the lower surface for example) makes it possible to dissociate the structural limitations (for example, the need for a particular curvature to ensure the lift of the structure and/or the fact that the envelope is generally subject to considerable mechanical stresses) and the optical limitations (for example, there is the option to adjust the profile of the at least partly reflective face to optimize the reflection phenomenon.)

Thus, the at least partly reflective wall undergoes lower mechanical stresses than the envelope itself, which makes it possible to use other materials than those of the envelope: secondly, the shape and geometry of said wall can be defined independently of the aerodynamic considerations governing the shape of the envelope.

FIG. 2 is a detail view of the wall 10 of the structure 1 illustrated in FIG. 1.

In this view, a module 2 is represented in cutaway.

The module 2 typically comprises a plurality of bifacial photovoltaic cells 20 arranged on a backing 21, the assembly of the cells and the backing being encapsulated in an encapsulant material that is at least partly transparent to solar radiation.

The backing 21 is for example polymer transparent to solar radiation, such as PMMA, PC, PET or FEP (Fluorinated ethylene propylene). Depending on the application, the backing 21 can also be made of thin glass, such as a glass with a thickness less than or equal to 0.8 mm and having a certain flexibility.

Each bifacial cell 20 comprises an outer face 200 intended to be exposed to solar radiation and an inner face 201 facing the outer face 100 of the wall 10. The two faces 200 and 201 are photoactive.

A part 11 of the incident radiation coming from the sun S is transmitted through the outer face 200 of each cell.

Moreover, the interval between the modules and, advantageously, between the cells of one and the same module, exposes the regions 102 of the wall 10 to solar radiation, the regions transmit a part T2 of said radiation toward the inner space 12.

This transmitted radiation T2 passes through the inner space 12 toward the wall 11 and reflects off the reflective face 110 of said wall.

A part R3 of this reflected radiation passes through the inner space 12 and is transmitted through the partly transparent wall 10, then through the inner face 201 of the bifacial cells 20 which are arranged thereon.

Thus, the wall 11 makes it possible to recover a significant part of the radiation that enters the inner space 12 and to consequently increase the electrical power produced by the structure.

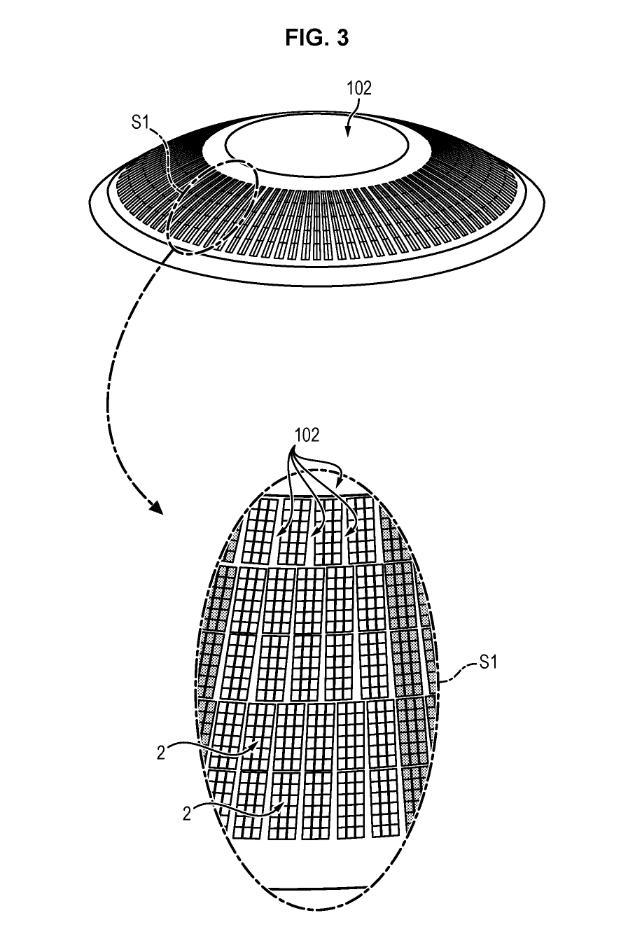

FIG. 3 is a perspective view of the upper surface of the structure of FIG. 1.

The photovoltaic modules 2 are arranged on the wall 10, which is here in the shape of a dome so as to form a ring extending over a certain height, the lower part linked to the lower surface and the apex of the upper surface not supporting the photovoltaic modules. Other shapes with a vertical axis or plane of symmetry are also possible, such as pyramidal shapes for example, as well as elliptical shapes with a horizontal axis of symmetry.

The modules are preferably arranged reversibly on the first wall, which allows them to be replaced. Particularly advantageously, all the modules 2 are identical, which simplifies the maintenance and management of spare parts.

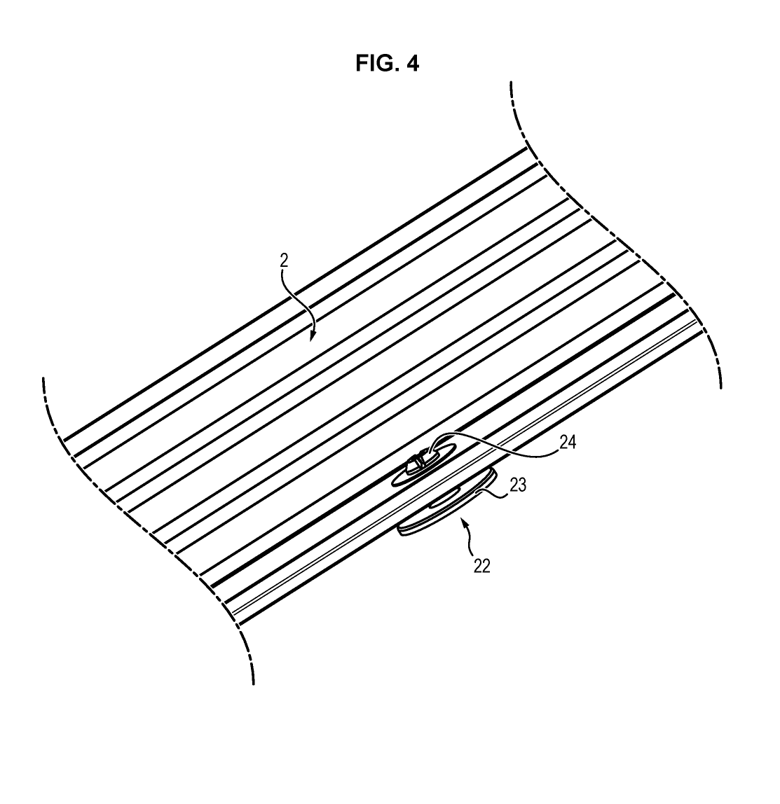

FIG. 4 illustrates an example of a component 22 for fastening a module 2 to the first wall (which is not represented.)

Said fastening component 22 comprises a base 23 intended to be fastened to the first wall and a nipple extending from the base 23 through a passage formed in the module 2.

Preferably, the modules 2 have a rectangular shape.

The number and dimensions of the photovoltaic modules are advantageously chosen according to the dimensions of the structure 1 and the mass that it can carry.

There is therefore an interval between two adjacent modules, as well as at the apex of the upper surface, which leaves a portion 102 of the surface of the underlying layer 10 exposed.

The circumference of the ring is divided into a plurality of angular sectors: in the example illustrated here, a sector s1 comprises 26 modules.

The modules belonging to one and the same sector are electrically connected in series.

The sectors are electrically connected in parallel to a current converter which is itself linked to at least one electrical battery constituting the energy source of the structure 1.

This arrangement of the structure 1 thus makes it possible to recover a significant part of the solar radiation and thus increase the unit output of each photovoltaic cell, for a constant mass.

The invention thus makes use of the areas 102 of the wall 10 which are not masked by photovoltaic modules to increase the output of photovoltaic conversion of each module without the mass borne by the structure being increased.

Preferably, the structure has at least one axis or one plane of symmetry. This is because this symmetry makes it possible to compensate for non-uniform lighting of the structure and to make uniform the photovoltaic production of an angular sector between two opposite angular sectors.

The modules are advantageously arranged in at least four angular sectors, so as to make the photovoltaic production of a pair of diametrically opposed angular sectors uniform. The number of angular sectors will in particular be adapted to the particular shape of the structure and the type of application chosen.

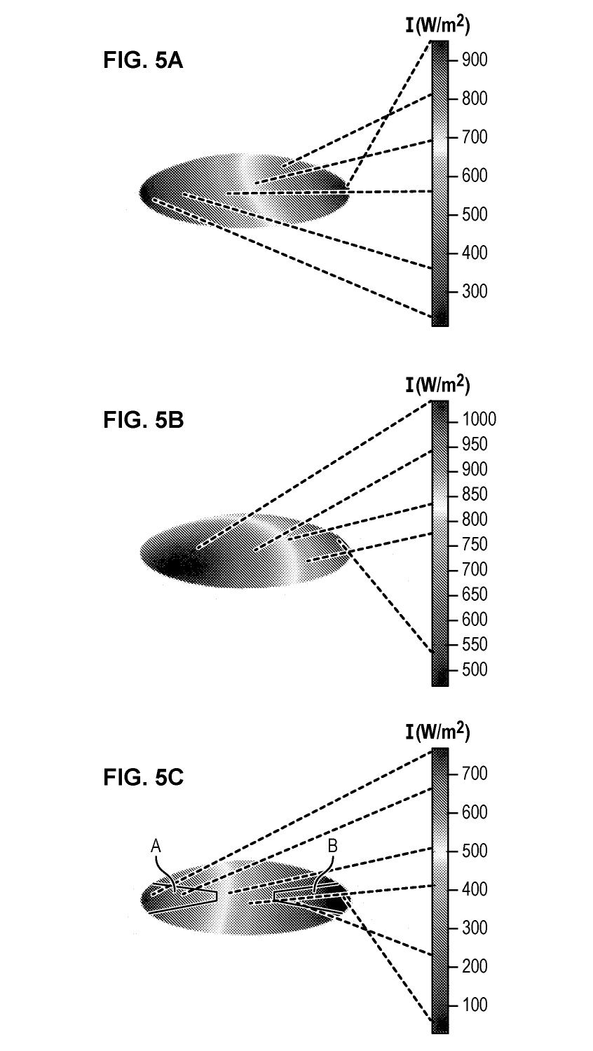

FIGS. 5A to 5C illustrate the distribution of the irradiation of the solar radiation over the surface of the first wall of a structure similar to those in FIGS. 1 to 3 at three times in a day, namely 8:30 a.m., 2:00 p.m. and 5:30 p.m. respectively.

It can therefore clearly be seen that according to the time of day, the lighting of a given sector of the structure—and consequently the power produced—varies noticeably.

For example, in the case of FIG. 5C, the angular sector A that is the most well-lit can generate far more photovoltaic electrical power than the angular sector B that is diametrically opposite it. Numerical simulations show that the differences between the electrical powers produced by two sectors can vary by a few percent in the most favorable scenario (when the two sectors are pointed North and South respectively) and reach a factor of 5 in the least favorable scenario (when the two sectors are pointed East and West respectively.)

In these unfavorable scenarios, allowing a part of the radiation to which a sector subject to strong lighting is exposed to rejoin a sector subject to weak lighting, by reflecting off the partly reflective inner face 110, potentially allows the latter to produce an electrical power nearly equivalent to that of the first, even taking into account the transmission losses of the wall 10, the losses in the reflection of the rays and the losses due to the shadowing induced by the modules of the first sector. It is estimated that the difference in electrical production between two diametrically opposite sectors can then be reduced by at least a half.

Naturally, the structure may have another distribution of modules than that illustrated in FIG. 3 without however departing from the scope of the present invention.

In the embodiment in FIG. 1, the wall 11 is planar. The frame 13 therefore comprises means for exerting a tensile force on the wall 11 and keeping it planar.

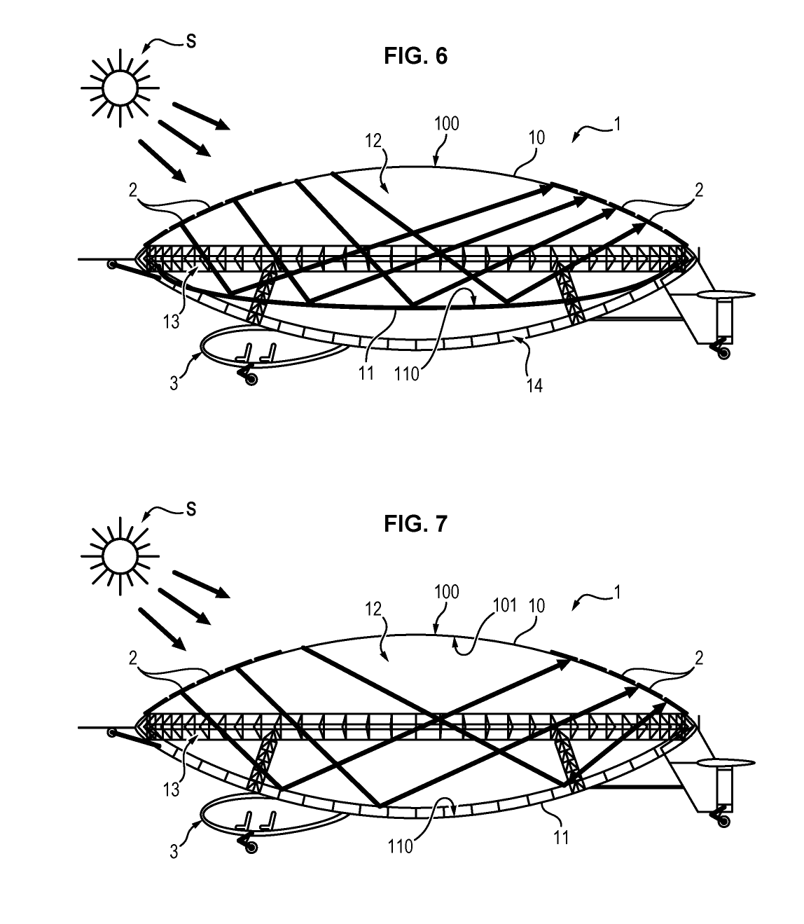

FIG. 6 illustrates a variant of the embodiment in FIG. 1, wherein the wall 11 has a concave curvature optimized to guide the solar radiation transmitted through one sector of the structure toward the opposite sector and thus make the production of this pair of sectors uniform.

Optical simulations make it possible to define the optimal curvature of the wall 11 as a function of the positioning of the modules on the wall 10, and particularly according to their organization in sectors, while taking into account the requirement for uniformity in the radiation at the back face and any focusing requirements.

The wall 11 can have a planar or curved shape that is constant over time.

Alternatively, the structure can comprise a device for actuating the wall 11 with a view to adjusting the curvature of said wall as a function of the position of the structure with respect to the sun in order to be able to optimize the electrical performance instantaneously

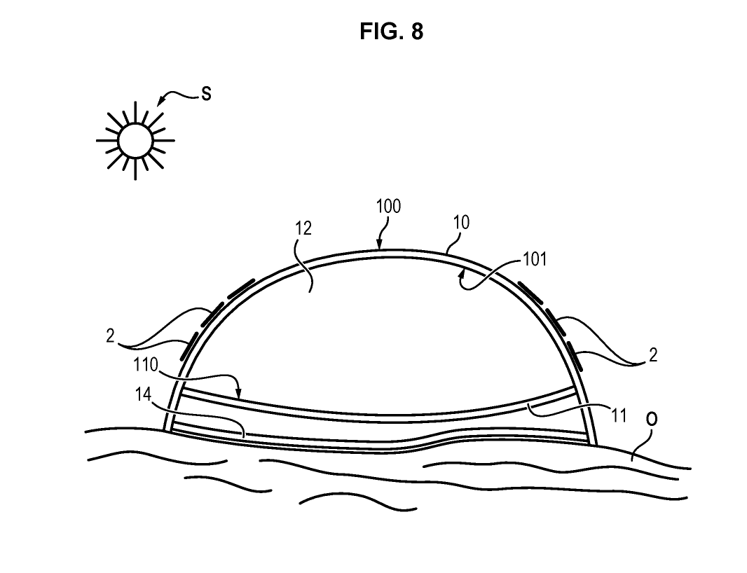

FIG. 7 illustrates a photovoltaic structure which, like those in FIGS. 1 and 6, forms an airship. In this structure, the wall 11, which has an at least partly reflective face, forms the lower surface, i.e. it is part of the envelope itself. The at least partly reflective surface 110 is arranged facing the inner face 101 of the first wall 10. The two walls 10, 11 are held together by the rigid frame 13 and thus form a closed and watertight envelope delimiting an inner space 12 containing a carrier gas consisting in a light compressed gas to maintain the curvature of the two walls required for the lift of the structure. The wall 11 is made of a light material, which can be identical or different to that of the wall 10, and covered with a reflective layer on the face 110.

FIG. 8 illustrates another type of structure designed in accordance with the invention. In this case it is a structure intended to float on an ocean O.

Such a structure comprises an envelope made of a first at least partly transparent wall 10 forming a dome and another wall 13 intended to be sat on the surface of the ocean.

The wall 11 comprising an at least partly reflective face is arranged inside this envelope.

The wall 10 supports a plurality of photovoltaic modules 2, preferably arranged into sectors.

For this application the materials must be suited to the limitations of the maritime environment, in particular humidity, water salinity, swell and wind.

The invention is also applicable to light structures (such as dismountable marquees or inflatable structures) equipped with photovoltaic panels and intended for various types of event (sporting or other types.)

1. A photovoltaic structure comprising a first wall and a second wall defining an inner space therebetween,
the first wall being at least partly transparent to solar radiation and comprising an outer face intended to be exposed to solar radiation and an inner face,
the second wall comprising an inner face facing the inner face of the first wall, said inner face of the second wall being at least partly reflective with regard to solar radiation, the first wall forming a part of a closed envelope and the second wall being arranged inside said envelope,
a plurality of photovoltaic modules each comprising a plurality of bifacial solar cells, said modules being arranged on the outer face of the first wall, each bifacial cell comprising an outer face intended to be exposed to incident solar radiation and an inner face facing the outer face of the first wall,
so that when the structure is exposed to solar radiation, a first portion of the incident radiation is transmitted toward the outer face of said bifacial photovoltaic cells, a second portion of said incident radiation is transmitted through a part of the first wall and at least partly reflects off the inner face of the second wall, said reflected portion being transmitted through the first wall toward the inner face of the bifacial photovoltaic cells.

2. The structure according to claim 1, wherein the photovoltaic modules are arranged in a non-contiguous way on the first wall, a portion of the incident radiation being transmitted through a part of the first wall located between two non-contiguous photovoltaic modules.

3. The structure according to claim 1, wherein the second wall is planar.

4. The structure according to claim 1, wherein the second wall has a curvature adjusted as a function of the curvature of the first wall and of the distribution of the photovoltaic modules on the first wall to optimize the reflection of the incident radiation transmitted through a region of the first wall toward the inner face of the cells of said modules located in the opposite region of said first wall.

5. The structure according to claim 1, comprising a device for actuating the second wall, adapted to adjust the curvature of said second wall as a function of the position of the structure with respect to the sun.

6. The structure according to claim 1, having at least one plane or one axis of symmetry.

7. The structure according to claim 1, wherein the first wall has a convex rotational shape and the photovoltaic modules are distributed over said first wall in a plurality of angular sectors, the photovoltaic modules of one and the same angular sector being linked in series.

8. The structure according to claim 7, wherein a summit portion of the first wall is without photovoltaic modules.

9. The structure according to claim 1, wherein all the photovoltaic modules arranged on the first wall are identical.

10. The structure according to claim 1, wherein the photovoltaic modules are arranged reversibly on the first wall.

11. The structure according to claim 1, wherein the material of the first wall comprises a glass fiber fabric.

12. The structure according to claim 1, wherein the second wall is made of polyethylene terephthalate (PET) metallized on its inner face.

13. A lenticular airship comprising a structure according to claim 1, the envelope of said structure being filled with a carrier gas.

14. A dome specifically intended to float on the surface of a sea or an ocean, comprising a structure according to claim 1.
